(19) United States
(12) Patent Application Publication
(10) Pub. No.: US 2025/0092522 A1
(43) Pub. Date: Mar. 20, 2025

(54) SEMICONDUCTOR PROCESSING APPARATUS AND SEMICONDUCTOR DEVICE MANUFACTURING METHOD USING THE SAME

(71) Applicant: Samsung Electronics Co., Ltd., Suwon-si (KR)

(72) Inventor: Jinbum Kim, Suwon-si (KR)

(21) Appl. No.: 18/669,753

(22) Filed: May 21, 2024

(30) Foreign Application Priority Data
Sep. 19, 2023 (KR) 10-2023-0124893

(51) Int. Cl. C23C 16/46; C23C 16/44; C23C 16/455; C23C 16/48; C23C 16/52; H01L 21/02

(52) U.S. Cl. CPC C23C 16/46; C23C 16/4412; C23C 16/482; C23C 16/52; H01L 21/0245; C23C 16/45523

(57) ABSTRACT

A semiconductor processing apparatus includes a support configured to support a wafer, a chamber including an upper dome and a lower dome, a facility cover that at least partially surrounds the chamber, a pre-heating unit that is below the support and is configured to heat the wafer, an upper lamp that is on the chamber and is configured to heat the wafer, a first process gas supply unit configured to supply a first process gas to the chamber, a second process gas supply unit configured to supply a second process gas to the chamber, a valve that is between the second process gas supply unit and the chamber, a pump that is connected to the chamber and is configured to discharge gas from the chamber, and a control unit, where the pre-heating unit includes a first lamp that is different from the upper lamp.

### CROSS-REFERENCE TO RELATED APPLICATION

This application claims the priority and benefit of Korean Patent Application No. 10-2023-0124893, filed on Sep. 19, 2023, with the Korean Intellectual Property Office, the present disclosure of which is incorporated herein by reference.

### TECHNICAL FIELD

The present disclosure relates to a semiconductor processing apparatus and a semiconductor device manufacturing method using the same.

### BACKGROUND

As the demand for high performance, high speed, and/or multifunctionality of semiconductor devices increases, a degree of integration of semiconductor devices is increasing. In manufacturing fine-patterned semiconductor devices in response to the trend toward high integration of semiconductor devices, it is desirable to implement patterns with fine widths or fine spacing. In addition, there is a need for semiconductor processing apparatuses and methods for forming thinner films used in semiconductor devices.

### SUMMARY

An aspect of the technical problems to be solved by the technical idea of the present disclosure is to provide a semiconductor processing apparatus including a pre-heating unit and an upper lamp, which is a flash lamp. In addition, an aspect of the present disclosure is to provide a semiconductor device manufacturing method using the semiconductor processing apparatus.

According to aspects of the present disclosure, a semiconductor processing apparatus may include: a support configured to support a wafer, a chamber including an upper dome that is above the support and a lower dome that is below the support, a facility cover that at least partially surrounds the chamber, a pre-heating unit that is below the support and is configured to heat the wafer, an upper lamp that is on the chamber and is configured to heat the wafer, a first process gas supply unit configured to supply a first process gas to the chamber, a second process gas supply unit configured to supply a second process gas to the chamber, a valve that is between the second process gas supply unit and the chamber, a pump that is connected to the chamber and is configured to discharge gas from the chamber, and a control unit that is configured to execute instructions stored in a non-transitory storage medium, where the instructions include controlling the pre-heating unit, the upper lamp, the first process gas supply unit, and the second process gas supply unit, where the pre-heating unit includes a first lamp that is different from the upper lamp.

According to aspects of the present disclosure, a semiconductor processing apparatus may include: a chamber that includes a support configured to support a wafer, a pre-heating unit that is below the support, an upper lamp that is above the support, and a control unit that is configured to execute instructions stored in a non-transitory storage medium to control the semiconductor processing apparatus to perform operations including: depositing metal on the wafer, heating the metal to form a metal-semiconductor compound layer on the wafer, and growing a thin film between the wafer and the metal-semiconductor compound layer, where growing the thin film includes forming a first thin film and forming a second thin film on the first thin film, where forming the first thin film includes: supplying a first process gas to the chamber, heating the wafer using the pre-heating unit below the wafer, and heating the wafer using the upper lamp to grow the first thin film.

According to aspects of the present disclosure, a semiconductor device manufacturing method may include: depositing metal on a wafer; heating the metal to form a metal-semiconductor compound layer on the wafer; disposing the wafer on a support inside a chamber covered by a lower dome and an upper dome on the lower dome; and growing a thin film between the wafer and the metal-semiconductor compound layer. The growing the thin film may include forming a first thin film and forming a second thin film on the first thin film. The forming the first thin film may include: supplying a first process to the chamber; first pre-heating the wafer using a pre-heating unit disposed below the wafer; and first heating the wafer using an upper lamp disposed above the chamber to grow a first thin film below the metal-semiconductor compound layer.

According to aspects of the present disclosure, a semiconductor processing apparatus may include: a support configured to support a wafer, a chamber including an upper dome that is above the support and a lower dome that is below the support, a facility cover that at least partially surrounds the chamber, a pre-heating unit that is below the support and is configured to heat the wafer, an upper lamp that is on the chamber and is configured to heat the wafer, a gas inlet on a first side of the chamber, a gas outlet on a second side of the chamber, a first process gas supply unit that is connected to the gas inlet and is configured to supply a first process gas to the chamber, a second process gas supply unit that is connected to the gas inlet and is configured to supply a second process gas to the chamber, a valve that is between the second process gas supply unit and the chamber, a pump that is connected to the gas outlet and is configured to discharge gas from the chamber, and a control unit that is configured to execute instructions stored in a non-transitory storage medium, where the instructions include controlling the pre-heating unit, the upper lamp, the first process gas supply unit, and the second process gas supply unit, where the pre-heating unit includes a first lamp that is different from the upper lamp, where the instructions include controlling the pre-heating unit to heat the wafer before a thin film growth process is performed, and where the instructions include controlling the upper lamp to heat the wafer when the thin film growth process is performed.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a schematic configuration diagram of a semiconductor processing apparatus according to an example embodiment;

FIG. 2 is a diagram illustrating a thin film growth method according to example embodiments;

FIG. 3 is a diagram illustrating a thin film growth method according to example embodiments;

FIG. 4 is a flow chart illustrating a thin film growth method according to an example embodiment;

FIG. 5 is a diagram illustrating a thin film growth method according to an example embodiment;

FIG. 6 is a diagram illustrating a thin film growth method according to an example embodiment;

FIG. 7 is a diagram illustrating a thin film growth method according to an example embodiment;

FIG. 8 is a flow chart illustrating a thin film growth method according to an example embodiment;

FIG. 9 is a diagram illustrating a thin film growth method according to an example embodiment;

FIGS. 10 and 11 are schematic configuration diagrams of a semiconductor processing apparatus according to an example embodiment;

FIG. 12 is a schematic configuration diagram of a substrate processing apparatus according to an example embodiment;

FIG. 13 is a flow chart illustrating a semiconductor device manufacturing method according to an example embodiment; and

FIGS. 14, 15, and 16 are diagrams illustrating a semiconductor device manufacturing method according to an example embodiment.

### DETAILED DESCRIPTION

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical, fluid, and/or electrical connection and may refer to a direct or indirect physical and/or electrical connection.

The present disclosure has been described herein with reference to flowchart and/or block diagram illustrations of methods, systems, and devices in accordance with exemplary embodiments of the invention. It will be understood that each block of the flowchart and/or block diagram illustrations, and combinations of blocks in the flowchart and/or block diagram illustrations, may be implemented by computer program instructions and/or hardware operations. These computer program instructions may be provided to a processor of a general purpose computer, a special purpose computer, or other programmable data processing apparatus to produce a machine, such that the instructions, which execute via the processor of the computer or other programmable data processing apparatus, create means for implementing the functions specified in the flowchart and/or block diagram block or blocks.

These computer program instructions may also be stored in a non-transitory computer usable or computer-readable memory that may direct a computer or other programmable data processing apparatus to function in a particular manner, such that the instructions stored in the computer usable or computer-readable memory produce an article of manufacture including instructions that implement the function specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions that execute on the computer or other programmable apparatus provide steps for implementing the functions specified in the flowchart and/or block diagram block or blocks.

Hereinafter, example embodiments of the present disclosure will be described with reference to the accompanying drawings as follows.

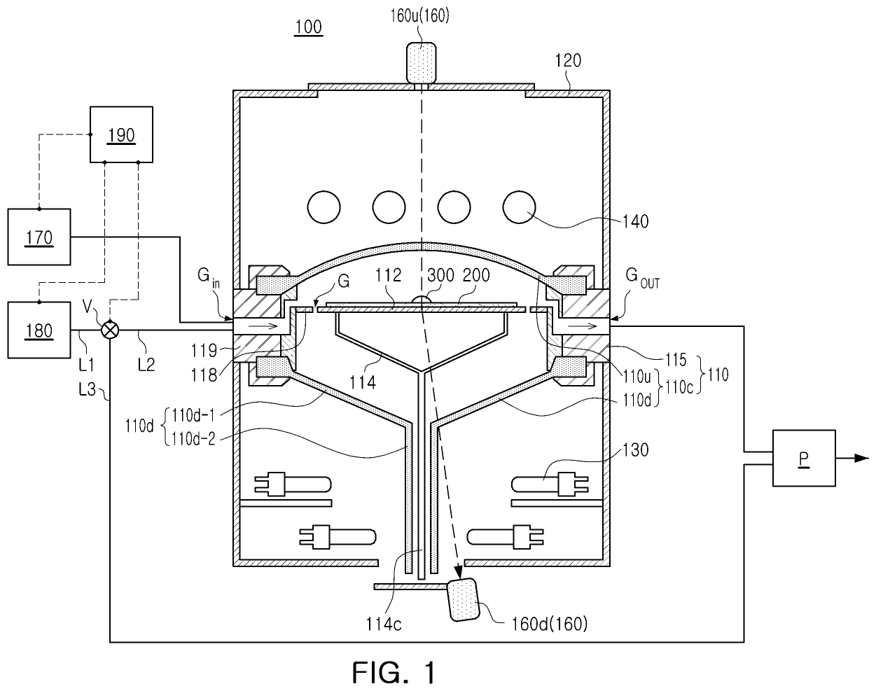

FIG. 1 is a schematic configuration diagram of a semiconductor processing apparatus according to an example embodiment.

Referring to FIG. 1, the semiconductor processing apparatus 100 of the embodiment may include a chamber 110, a facility cover 120, a pre-heating unit 130, an upper lamp 140, a pyrometer 160, a first gas supply unit 170, a second gas supply unit 180, a valve V, a pump P, and a control unit 190. A wafer 200 may be disposed in a chamber 110.

The chamber 110 may include a chamber body 115 and a cover dome 110c. The chamber 110 may be a deposition chamber for growing a thin film on a deposition target, for example, a wafer 200. In an example embodiment, a metal-semiconductor compound layer may be disposed on the wafer 200, and the semiconductor processing apparatus 100 of the present disclosure may be used to grow a thin film between the wafer 200 and the metal-semiconductor compound layer. For example, the chamber 110 may be a chamber for epitaxial growth (EG) or Selective Epitaxial Growth (SEG), a Low Pressure Chemical Vapor Deposition (LPCVD) chamber, or a Very Low Pressure Chemical Vapor Deposition (VLPCVD) chamber. However, the chamber 110 is not limited to the above-described chambers.

The chamber body 115 may have a cylindrical shape with open upper and lower portions. For example, the chamber body 115 may have a cylindrical shape. However, the shape of the chamber body 115 is not limited thereto. In some example embodiments, the chamber body 115 may have a polygonal barrel shape. Part or all of the chamber body 115 may be made of a metallic material. For example, the chamber body 115 may be formed of a metallic material, such as aluminum or stainless steel.

The cover dome 110c may include an upper dome 110u and a lower dome 110d. The upper dome 110u is disposed above the chamber body 115 and may have a dome shape, which is convex upwardly. A lower portion, which is an edge portion, of the upper dome 110u may be attached to an upper surface of the chamber body 115 to define and seal an upper region of a reaction space within the chamber 110. The upper dome 110u may have a detachable structure and may be attached to the chamber body 115. Accordingly, the upper dome 110u may be separated from the chamber body 115 and cleaned or replaced with a new upper dome.

The upper dome 110u may be formed of a material that may effectively transfer radiant heat or energy from the upper lamp 140 installed above the chamber 110 to the reaction space within the chamber 110. For example, the upper dome 110u may be formed of a light-transmitting material, such as quartz, which is transparent to ultraviolet (UV) light, visible light, and infrared (IR) light. A material of the upper dome 110u is not limited to quartz. For example, the upper dome 110u may be formed of light-transmitting ceramic. In addition, at least a portion of the upper dome 110u may be formed of an opaque material. Since the upper dome 110u is formed of a light-transmitting material, radiant heat or energy from the upper lamp 140 may pass through the upper dome 110u and be transferred to the reaction space within the chamber 110.

The lower dome 110d may be attached to a lower surface of the chamber body 115 to define and seal a lower region of a reaction space within the chamber 110. The lower dome 110d may also be formed of a light-transmitting material, such as quartz. Accordingly, the lower dome 110d may effectively transfer radiant heat or energy from the pre-heating unit 130 disposed below the chamber 110 to the reaction space inside the chamber 110. Like the upper dome 110u, the lower dome 110d may be formed of a light-transmitting ceramic, or at least a portion thereof may be formed of an opaque material.

As illustrated in FIG. 1, the lower dome 110d may include a bottom plate 110d-1 inclined downwardly and an extension pipe 110d-2 extending to protrude or extend from a center of the bottom plate 110d-1 downwardly. The bottom plate 110d-1 may have an inverted cone shape with an open upper portion. The extension pipe 110d-2 may have a shape, such as a cylindrical cylinder.

A support 112 on which a deposition object, for example, a wafer 200, is placed is disposed in a central portion of the chamber 110, and the support 112 may be supported by a tripod or a hexagon 114. A central axis 114c of the tripod or the hexagon 114 may extend downwardly through an extension pipe 110d-2, and may be connected to a rotation driver (not shown). Accordingly, the support 112 may rotate at a constant speed by the rotation driver. The support 112 is sometimes referred to as a susceptor.

A pre-heating ring 118 may be disposed on an outside of the support 112, and an insert 119, such as a quartz ring, may be disposed on an inner surface of the chamber body 115 adjacent to the support 112. The insert 119 may form a portion of the chamber body 115. Meanwhile, a gap (G) may be between the pre-heating ring 118 and the support 112, and process gases may be moved to the reaction space below the support 112 through the gap G.

In one variation, a pressure adjusting device, a pressure measuring device, and various inspection or monitoring devices for monitoring an internal state of the chamber 110 may be further installed inside and outside the chamber 110. A gas inlet (Gin) through which process gases flow may be disposed on one side of the chamber 110, and a gas outlet (Gout) through which impurities after reaction or unreacted gases are discharged may be disposed on the other side of the chamber 110. The gas inlet (Gin) and the gas outlet (Gout) may be disposed on opposite sides of the chamber 110 with the wafer 200 interposed therebetween. However, dispositional positions of the gas inlet (Gin) and gas outlet (Gout) are not limited thereto. The gas outlet (Gout) may be connected to a pump P disposed outside a facility cover 120. The impurities after reaction or unreacted gases may be discharged externally by a pump P.

The facility cover 120 is a type of housing supporting a chamber 110, and may at least partially surround the chamber 110 to block or isolate the chamber 110 from the outside (e.g., an ambient environment). The facility cover 120 may generally be formed of a metal material. However, a material of the facility cover 120 is not limited to a metal material. In some example embodiments, a view-port may be installed in the facility cover 120 so that the inside of the chamber 110 may be viewed from the outside.

The pre-heating unit 130 may be disposed below the chamber 110. For example, the pre-heating unit 130 may be disposed within the facility cover 120, and may be supported by the facility cover 120. The pre-heating unit 130 may supply radiant heat or energy to the chamber 110 to preliminarily heat the wafer 200 before depositing a thin film on the wafer 200. In an example embodiment, the pre-heating unit 130 may include a halogen lamp. A plurality of pre-heating units 130, which are halogen lamps, may be disposed in the lower portion of the chamber 110. For example, the pre-heating unit 130 may be configured to heat the wafer 200 to a temperature below a eutectic temperature of the metal-semiconductor compound layer disposed on the wafer 200 in the chamber 110. As described above, since the lower dome 110d is formed of a light-transmitting material, light emitted from the pre-heating unit 130 may be supplied to the chamber 110. Although not illustrated, a plurality of lamp reflectors may be disposed in various manners inside the facility cover 120 to effectively induce light from the pre-heating unit 130 to be supplied to the chamber 110.

In an example embodiment, the pre-heating unit 130 may include an ultraviolet (UV) lamp. The UV lamp may use, for example, a mercury-based arc lamp (Hg-based arc lamp).

The upper lamp 140 may be placed on chamber 110. For example, the upper lamp 140 may be disposed within the facility cover 120, and may be supported by the facility cover 120. The upper lamp 140 may supply radiant heat or energy to the chamber 110 to heat the wafer 200 and the metal-semiconductor compound layer in order to deposit a thin film on the wafer 200.

The upper lamp 140 may include a lamp different from a lamp of the pre-heating unit 130. In an example embodiment, the upper lamp 140 may be a flash lamp configured to operate in milliseconds. For example, the upper lamp 140 may be an argon arc lamp or a xenon arc lamp. A plurality of upper lamps 140 may be disposed on the chamber 110. For example, the upper lamp 140 may be configured to heat the wafer 200 to a temperature above a eutectic temperature of the metal-semiconductor compound layer disposed on the wafer 200 in the chamber 110. As described above, since the upper dome 110u is formed of a light-transmitting material, light emitted from the upper lamp 140 may be supplied to the chamber 110. In an example embodiment, the upper lamp 140 may operate in a time range of about 0.1 ms to about 5 ms.

The pyrometer 160 may include an upper pyrometer 160u disposed on an upper surface of the facility cover 120 and a lower pyrometer 160d disposed on a lower surface thereof. A position and number of pyrometers 160 are not limited thereto. The pyrometer 160 may be a non-contact optical pyrometer. An optical pyrometer may be used to measure a temperature by comparing luminance of a measured object to that of a standard lamp, and measure a temperature of a high-temperature object where a thermometer cannot be inserted directly. However, the pyrometer 160 is not limited to an optical pyrometer. For example, the pyrometer 160 may be a radiation pyrometer using radiant heat, or a photoelectric pyrometer that uses photocurrent generated by radiation.

The first gas supply unit 170 may be configured to supply a first process gas to the chamber 110. The first gas supply unit 170 may be connected to a gas inlet (Gin) formed on one side of the chamber 110. Byproducts of the first process gas supplied from the first gas supply unit 170 and unreacted first process gas may be discharged externally of the chamber 110 through a gas outlet (Gout). In an example embodiment, the first process gas may be a silicon source gas for growing silicon (Si) from the wafer 200 below the metal-semiconductor compound layer. For example, the first process gas may include at least one of SiH₄, Si₂H₆, SiCl₂H₂, SiCl₃H, and SiCl₄.

The second gas supply unit 180 may be configured to supply a second process gas to the chamber 110. The second gas supply unit 180 may be connected to a gas inlet (Gin) formed on one side of the chamber 110. Byproducts of the first process gas supplied from the second gas supply unit 180 and unreacted first process gas may be discharged externally of the chamber 110 through a gas outlet (Gout). In an example embodiment, the second process gas may be supplied to the chamber 110 along with the first process gas and used to grow silicon germanium (SiGe) from the wafer 200 below the metal-semiconductor compound layer. For example, the second process gas may be a germanium source gas. For example, the second process gas may include at least one of GeH₄, Ge₂H₆, GeH₂Cl₂, GeCl₄, and Ge₂Cl₆.

The semiconductor processing apparatus 100 may further include a valve V disposed between a second gas supply unit 180 and a chamber. For example, the semiconductor processing apparatus 100 may further include a first supply line L1 connecting the second gas supply unit 180 and the valve V, a second supply line L2 connecting the valve V and a chamber 110, and an exhaust line L3 connecting the valve V and a pump P. The valve V may be configured to connect the first supply line L1 with one of the second supply line L2 and the exhaust line L3 and block the connection with the other. For example, the valve V may be configured to connect the first supply line L1 and the second supply line L2 to supply the first process gas to the chamber, or connect the first supply line L1 and the exhaust line to discharge the first process gas through the pump P.

The control unit 190 may be configured to control a first gas supply unit 170, a second gas supply unit 180, and a valve V. For example, after the wafer 200 is disposed within the chamber 110, the control unit 190 may control the first gas supply unit 170 to supply the first process gas to the chamber 110. During a first time period in which the growing silicon from the first process gas is performed, the control unit 190 may control the valve V so that the second process gas is discharged rather than being supplied to the chamber 110. In addition, during a second time period in which the growing SiGe from the wafer 200 is performed, the control unit 190 may control the valve V so that the second process gas is supplied to the chamber 110 together with the first process gas.

The control unit 190 may also control the pre-heating unit 130 to pre-heat the wafer 200, and control the upper lamp 140 to grow a thin film from the wafer 200.

The control unit 190 may be composed of, for example, a general PC (Personal Computer), a workstation, a supercomputer, or the like.

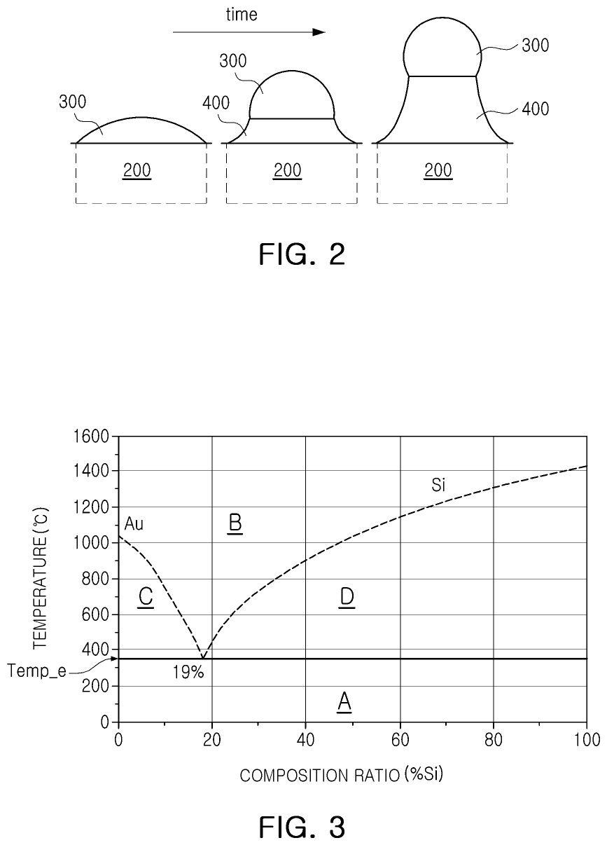

FIG. 2 is a diagram illustrating a thin film growth method according to example embodiments. FIG. 3 is a diagram illustrating a thin film growth method according to example embodiments. FIG. 2 illustrates a thin film growing from a wafer over time. FIG. 3 is a phase diagram according to a temperature and composition ratio of a metal-semiconductor compound layer.

Referring to FIGS. 2 and 3, silicon (Si) 400 may be grown on a lower surface of the metal-semiconductor compound layer 300 on the wafer 200. For example, referring to FIG. 3, the metal-semiconductor compound layer 300, which is a compound of gold (Au) and silicon (Si), may be in a solid state at a temperature below a eutectic temperature (Temp_e) (A). The eutectic temperature may be about 363° C. At the eutectic point, the silicon (Si) content may be about 19% and the gold (Au) content may be about 81 at %. When the silicon (Si) content is about 19 at % and the gold (Au) content is about 81 at %, the metal-semiconductor compound layer 300 may be in a liquid state at a temperature above a eutectic temperature (Temp_e) (B). In addition, when the silicon (Si) content of the metal-semiconductor compound layer 300 in the liquid state decreases, solid gold (Au) may precipitate from the liquid metal-semiconductor compound layer 300 (C). When the silicon (Si) content of the metal-semiconductor compound layer 300 in the liquid state increases, solid silicon (Si) may precipitate from the liquid metal-semiconductor compound layer 300 (D).

Referring again to FIG. 2, when a silicon source gas containing silicon, that is, a first process gas, is supplied to a liquid metal-semiconductor compound layer 300 on the wafer 200 at a temperature above the eutectic temperature, solid silicon (Si) 400 may precipitate at the interface between the liquid metal-semiconductor compound layer 300 and the wafer 200. Accordingly, silicon (Si) 400 may be deposited or grown between the wafer 200 and the metal-semiconductor compound layer 300.

As described above, the upper lamp 140 may heat the wafer 200 and the metal-semiconductor compound layer 300 to a temperature above a eutectic temperature, and may operate in a time range of about 0.1 ms to about 5 ms. The silicon (Si) may be grown to a thickness of about 1 nm to 1000 nm. When the metal-semiconductor compound layer 300 includes gold (Au) and silicon (Si), a silicon (Si) content may be about 14 at % to about 24 at %. A gold (Au) content may be about 71 at % to about 91 at %.

As described above, silicon (Si) is formed at an interface between the metal-semiconductor compound layer 300 and the wafer 200, so silicon (Si) may be selectively formed in a region in which a metal-semiconductor compound layer 300 is disposed. Silicon (Si) might not be formed in a region in which the metal-semiconductor compound layer 300 is not disposed.

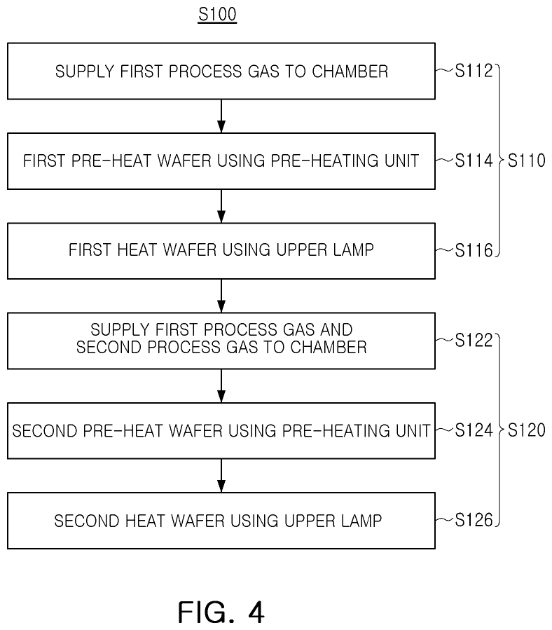

FIG. 4 is a flow chart illustrating a thin film growth method according to an example embodiment.

Referring to FIG. 4, a thin film growth method (S100) according to an example embodiment may include forming a first thin film (S110) and forming a second thin film (S120).

The forming of the first thin film (S110) may include supplying a first process gas to a chamber 110 (S112) and pre-heating a wafer 200 using a pre-heating unit 130 (S114), and heating a wafer 200 using an upper lamp 140 (S116).

The forming of the second thin film (S120) may be performed after forming the first thin film (S110). Alternatively, the forming the second thin film (S120) may be performed alternately and repeatedly with forming the first thin film (S110). The forming of the second thin film (S120) may include supplying a first process gas and a second process gas to a chamber 110 (S122) and pre-heating a wafer 200 using a pre-heating unit 130 (S124), and heating a wafer 200 using an upper lamp 140 (S126). In the pre-heating or heating the wafer 200, the metal-semiconductor compound layer 300 may also be heated.

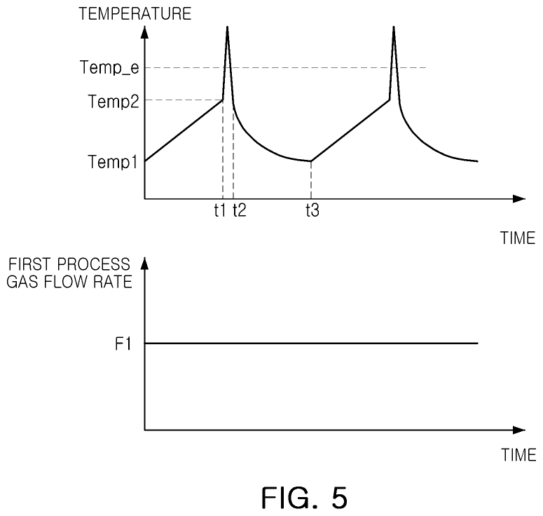

FIG. 5 is a diagram illustrating a thin film growth method according to an example embodiment. FIG. 5 is a diagram illustrating the formation of a first thin film (S110 in FIG. 4), and illustrates a flow rate of a first process gas according to a temperature and time of a wafer over time.

Referring to FIG. 5, while the process of forming the first thin film (S110) is performed, the first process gas may be provided into a chamber 110 at a constant flow rate (F1). The wafer 200 may be pre-heated using a pre-heating unit 130 until a first time point t1 (S114). The pre-heating unit 130 may heat the wafer 200 from a first temperature (Temp1) to a second temperature (Temp2). The second temperature (Temp2) may be lower than a eutectic temperature (Temp_e). The wafer 200 may be heated using an upper lamp 140 from a first time point t1 to a second time point t2 (S116). The upper lamp 140 may heat the wafer 200 to a temperature higher than the eutectic temperature (Temp_e). As the first process gas is continuously supplied to the chamber 110, the wafer 200 is heated to a temperature higher than the eutectic temperature (Temp_e), so that silicon (Si), which is a first thin film, may grow on the wafer 200. A time range from the first time t1 to the second time t2 when the upper lamp 140 operates may be about 0.1 ms to about 5 ms.

In an example embodiment, after the wafer 200 is heated by the pre-heating unit 130 (S116), the pre-heating unit 130 and the upper lamp 140 might not operate, and a temperature of the wafer 200 and the metal-semiconductor compound layer 300 may gradually decrease. Thereafter, the process of forming a first thin film (S100) may be repeated a plurality of times. For example, the control unit 190 may control the pre-heating unit 130 and the upper lamp 140 to operate alternately and repeatedly, and a plurality of first thin film layers may be formed.

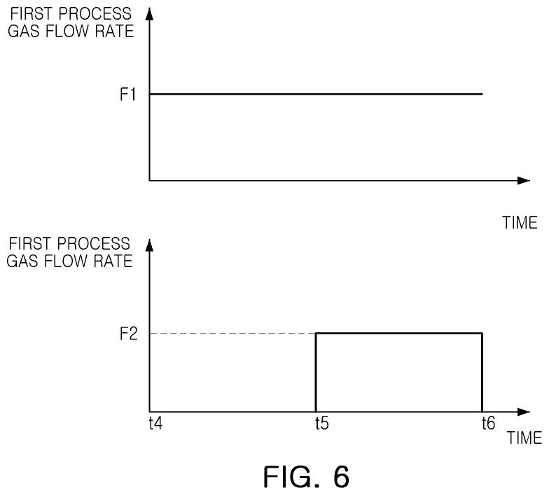

FIG. 6 is a diagram illustrating a thin film growth method according to an example embodiment.

Referring to FIG. 6, a process of forming a first thin film from a fourth time point (t4) to a fifth time point (t5) (S110) may be performed, and a process of forming a second thin film, silicon germanium (SiGe) (S120) from the fifth time point (t5) to the sixth time point (t6) may be performed. While the process of forming the first thin film (S110) and the process of forming the second thin film (S120) are performed, a first process gas may be provided into a chamber 110 at a constant flow rate (F1). From the fourth time point t4 to the fifth time point t5, a second process gas might not be provided into the chamber 110, and may be discharged externally through a pump P. The process of forming the first thin film (S110) may be performed in the same manner as described with reference to FIG. 5.

The second process gas may be supplied to the chamber 110 while the process of forming the second thin film (S120) is performed. For example, the second process gas may be supplied to the chamber 110 at a constant flow rate F2 from the fifth time point t5 to the sixth time point t6. In one embodiment, the flow rate F1 of the first process gas may be greater than a flow rate F2 of the second process gas.

The process of forming the second thin film (S120) may be performed similarly to that described with reference to FIG. 5.

First, a first process gas and a second process gas may be supplied to the chamber 110 (S122). The control unit 190 may control a valve V so that the second process gas is supplied to the chamber 110. A wafer 200 may be pre-heated using a pre-heating unit 130 (S124). The pre-heating unit 130 may pre-heat the wafer 200 to a temperature that is lower than a eutectic temperature (Temp_e). Thereafter, the wafer 200 may be heated using an upper lamp 140 (S126). The upper lamp 140 may heat the wafer 200 to a temperature higher than the eutectic temperature (Temp_e). An operating time range of the upper lamp 140 may be about 0.1 ms to about 5 ms. When the process of forming the second thin film (S120) is performed after the process of forming the first thin film (S110), a second thin film may be formed on the first thin film.

Since the semiconductor processing apparatus 100 of the present disclosure uses the upper lamp 140, which is a flash lamp, it is possible to heat the wafer 200 for a short time in order of milliseconds, and thus a thinner film may be formed from the wafer 200. Therefore, a semiconductor chip may be implemented with a fine pattern, and a size of the semiconductor chip may be reduced.

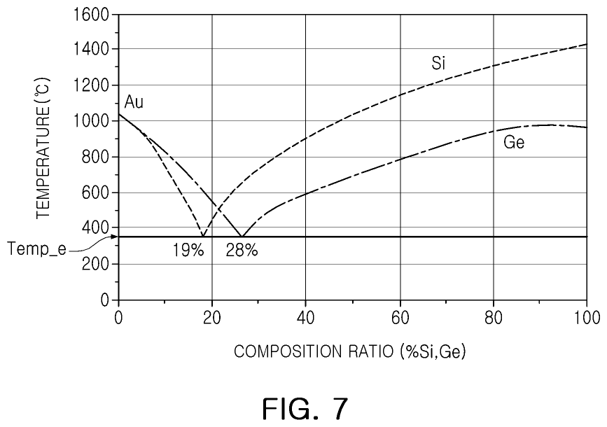

FIG. 7 is a diagram illustrating a thin film growth method according to an example embodiment. FIG. 7 is a phase diagram according to a temperature and composition ratio of a metal-semiconductor compound layer.

Referring to FIG. 7, when a metal-semiconductor compound layer 300 is formed of gold (Au) and germanium (Ge), a germanium (Ge) content is about 28 at % and a gold (Au) content is about 72 at %, the metal-semiconductor compound layer 300 may be present in a liquid state at a temperature above a eutectic temperature.

In an example embodiment, when silicon (Si), a first thin film, is formed, and then germanium (Ge), a second thin film, is formed, the metal-semiconductor compound layer 300 may contain not only gold (Au) and silicon (Si), but also a small amount of germanium (Ge). In this case, a eutectic point of the metal-semiconductor compound layer 300 containing all of gold (Au), silicon (Si), and germanium (Ge) may be between a eutectic point of the metal-semiconductor compound layer 300 formed of gold (Au) and silicon (Si) and a eutectic point of the metal-semiconductor compound layer 300 formed of gold (Au) and germanium (Ge).

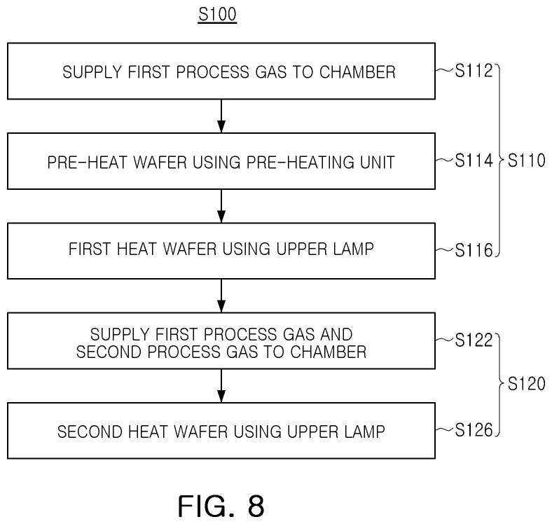

FIG. 8 is a flow chart illustrating a thin film growth method according to an example embodiment.

Referring to FIG. 8, a thin film growth method (S100) according to an example embodiment may include forming a first thin film (S110) and forming a second thin film (S120).

The forming the first thin film (S110) may include supplying a first process gas to a chamber 110 (S112), pre-heating a wafer 200 using a pre-heating unit 130 (S114), and heating the wafer 200 using an upper lamp 140 (S116).

The forming the second thin film (S120) may include supplying a first process gas and a second process gas to the chamber 110 (S122) and heating a wafer 200 using an upper lamp 140 (S126). Unlike the thin film growth method (S100) described with reference to FIG. 4, the pre-heating of the wafer 200 may continue during the thin film growth process.

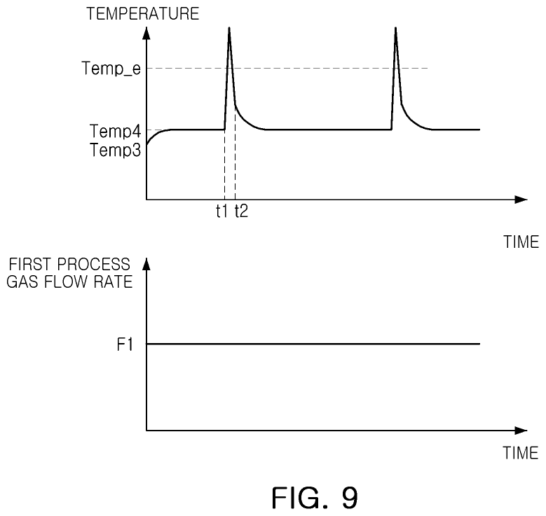

FIG. 9 is a diagram illustrating a thin film growth method according to an example embodiment. FIG. 9 is a diagram illustrating the thin film growth method (S100) of FIG. 8, and illustrates a temperature of a wafer 200 over time and a flow rate of a first process gas over time.

Referring to FIG. 9, while the process of forming the first thin film (S110) is performed, the first process gas may be provided into the chamber 110 at a constant flow rate F1. The wafer 200 may be pre-heated using a pre-heating unit pre-heating 130 until a first time point t1 (S114). The pre-heating unit 130 may heat the wafer 200 from a third temperature (Temp3) to a fourth temperature (Temp4). The fourth temperature (Temp4) may be lower than a eutectic temperature (Temp_e). In an example embodiment, the pre-heating unit 130 may be controlled by a control unit 190 to maintain the wafer 200 at a constant temperature. For example, while the upper lamp 140 is not operating, the wafer 200 may be heated by the pre-heating unit 130 to maintain the fourth temperature Temp4. For example, the pre-heating unit 130 may heat the wafer 200 to a constant temperature until the upper lamp 140 operates again after the second time point t2. In addition, even after the upper lamp 140 operates or while the second thin film process (S120) is performed after the first thin film process (S110), the pre-heating unit 130 may provide constant heat or energy to the wafer 200.

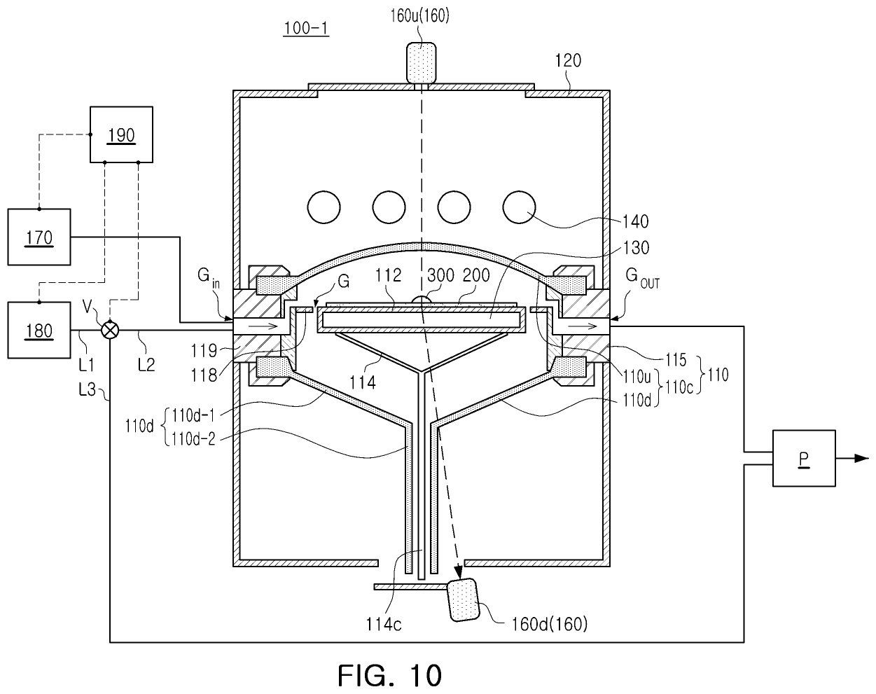

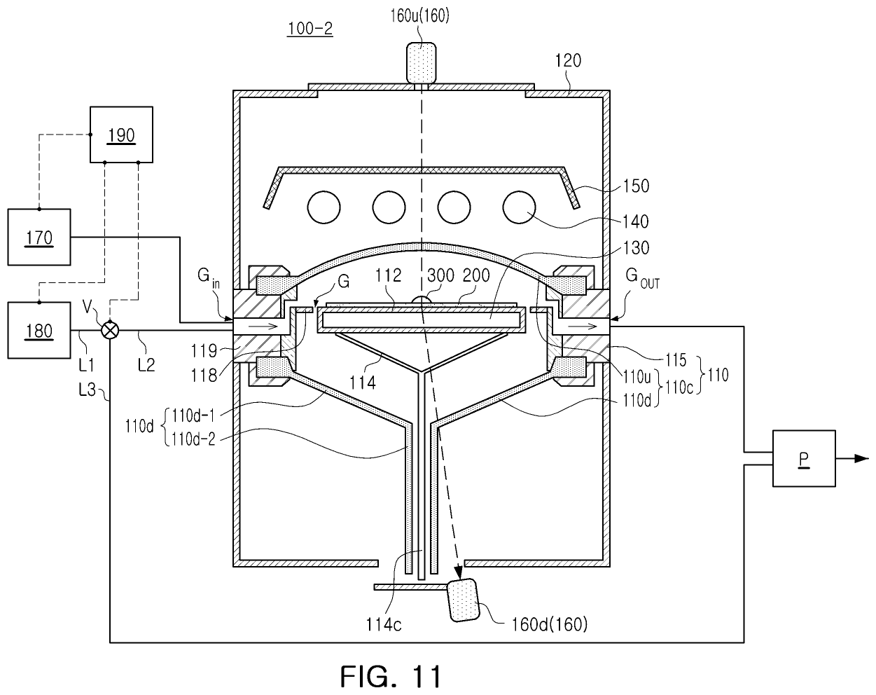

FIGS. 10 and 11 are schematic configuration diagrams of a semiconductor processing apparatus according to an example embodiment.

Referring to FIG. 10, a semiconductor processing apparatus 100-1 is shown and is similar to the semiconductor apparatus 100 shown in FIG. 1. In this example embodiment, the pre-heating unit 130 may be disposed inside a support 112 supporting the wafer 200. The pre-heating unit 130 may be configured to provide heat or energy to the wafer 200 through heat conduction.

Referring to FIG. 11, a semiconductor processing apparatus 100-2 is shown and is similar to the semiconductor apparatus 100 shown in FIG. 1. In one embodiment, the semiconductor processing apparatus 100-2 may further include a reflector 150 disposed on an upper lamp 140 within the facility cover 120. The reflector 150 may reflect light emitted from the upper lamp 140 and transmit the light to a wafer 200 inside the chamber 110. Accordingly, the wafer 200 may be heated more efficiently by the upper lamp 140.

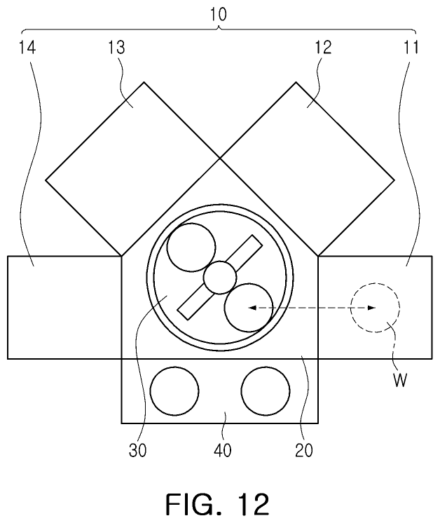

FIG. 12 is a schematic configuration diagram of a substrate processing apparatus according to an example embodiment.

Referring to FIG. 12, a semiconductor processing equipment 1 including one of the semiconductor processing apparatuses 100, 100-1, 100-2 according to an example embodiment of the present disclosure may include a plurality of process apparatuses 11 to 14 that perform a semiconductor process. For example, the plurality of process apparatuses 11 to 14 may include a deposition process chamber for performing a deposition process, a polishing process chamber for performing a chemical mechanical polishing (CMP) process, and an etching process chamber generating plasma containing radicals and ions of source gas or removing at least a portion of device layers included in a substrate W using an etchant, and the like. For example, at least one of the plurality of processing apparatuses 11 to 14 may be the semiconductor processing apparatus 100 described with reference to FIG. 1. The substrate W may correspond to the wafer 200 described with reference to FIG. 1. In addition, the plurality of processing apparatuses 11 to 14 may further include an inspection process chamber for inspecting the substrate W while the process is in progress or after the process is completed.

For example, the substrate W may be a semiconductor substrate on which a semiconductor process is performed, or may be a wafer that may be formed of a semiconductor material, such as silicon or the like. Semiconductor devices, wiring patterns connected to the devices, insulating layers covering or overlapping the semiconductor devices and wiring patterns, and the like may be formed on the substrate W by semiconductor processes performed in the plurality of process apparatuses 11 to 14, and a plurality of semiconductor chips may be produced from the substrate W.

For example, the plurality of process apparatuses 11 to 14 may receive a substrate W through a transfer chamber 20 and a load lock chamber 40 to perform a semiconductor process. The transfer chamber 20 and the load lock chamber 40 may include a transfer robot 30, and the transfer robot 30 of the transfer chamber 20 and the load lock chamber 40 may transfer the substrate W or the like (e.g., an object to be processed). For example, the transfer robot 30 of the transfer chamber 20 may take out a process object, such as a substrate W, from the load lock chamber 40 and transfer the process object to a plurality of process apparatuses 11 to 14, or transfer the process object between the plurality of process apparatuses 11 to 14. In an example embodiment, the transfer robot 30 may be a handler. The transfer robot 30 may include a chuck for fixing the process object, and a plurality of protrusions contacting the process object may be formed on an upper portion above the chuck. The transfer robot 30 may further include a linear stage for transferring the process object.

Referring to FIG. 12, the transfer robot 30 of the transfer chamber 20 according to an example embodiment of the present disclosure may remove a substrate W from a load lock chamber 40 and transfer the substrate W to the transfer chamber 20, and transfer the substrate W (e.g., a process object) to the processing apparatus 11. However, depending on embodiments, the process object might not be limited to wafers.

At least one of the process apparatuses 11 to 14 may be allocated as a chamber for performing a deposition process. In an example embodiment, the apparatus 11 may be a semiconductor processing apparatus in which the thin film growth process S100 described with reference to FIGS. 4 and 8 is performed.

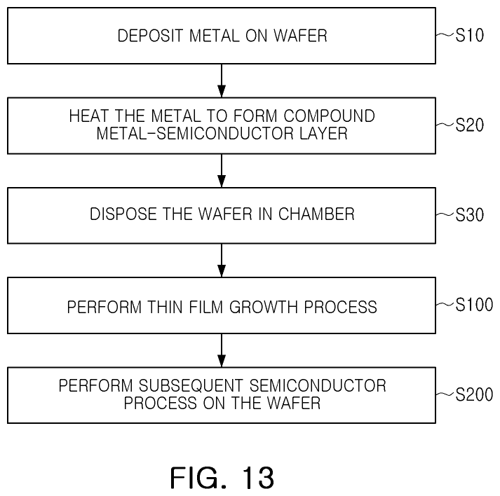

FIG. 13 is a flowchart illustrating a semiconductor device manufacturing method according to an example embodiment.

Referring to FIG. 13, the semiconductor device manufacturing method may include depositing metal on a wafer 200 (S10), heating the metal to form a metal-semiconductor compound layer 300 (S20), disposing the wafer 200 in a chamber 110 (S30), performing a thin film growth process (S100), and performing a subsequent semiconductor process on the wafer 200 (S200).

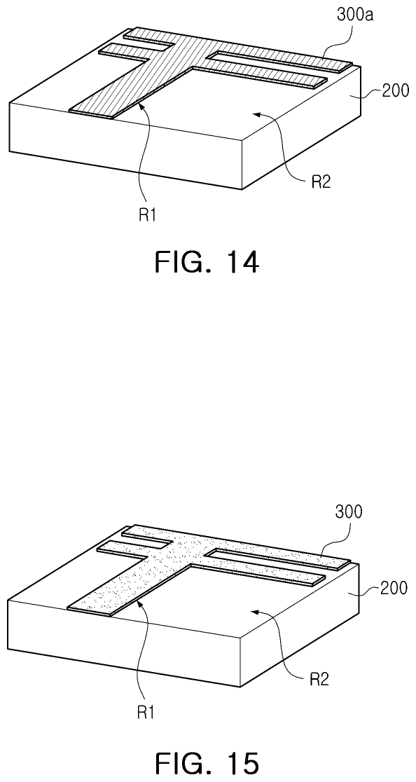

FIGS. 14 to 16 are diagrams illustrating a semiconductor device manufacturing method according to an exemplary embodiment. FIGS. 14 to 16 are diagrams illustrating depositing metal on a wafer 200 (S10), heating the metal to form a metal-semiconductor compound layer 300 (S20), disposing the wafer 200 in a chamber 110 (S30), and performing a thin film growth process (S100).

Referring to FIG. 14, metal 300a may be deposited on a wafer 200 (S10). In an example embodiment, the wafer 200 may include a silicon substrate and the metal 300a may be formed of gold (Au). In some example embodiments, the metal 300a may be formed of aluminum (Al), silver (Ag), zinc (Zn), titanium (Ti), palladium (Pd), or tungsten (W).

The metal 300a may be deposited on some regions on the wafer 200. For example, the metal may be deposited in a first region R1 of the wafer 200, and might not be deposited in a second region R2 of the wafer 200. The second region R2 may be adjacent to the first region R1. In an example embodiment, the first region R1 may correspond to a cell region in which memory cells of a memory device are disposed, and the second region R2 may correspond to a peripheral circuit region in which peripheral wirings of the memory device are disposed.

Referring to FIG. 15, the metal 300a may be heated to form a metal-semiconductor compound layer 300 (S20). For example, the gold (Au) and silicon (Si) may chemically react to form a metal-semiconductor compound layer 300 formed of gold (Au) and silicon (Si). The metal-semiconductor compound layer 300 may be formed in the first region R1 of the wafer 200. As described above, the metal-semiconductor compound layer 300, which has a silicon (Si) content of about 19 at % and a gold (Au) content of about 81 at %, may have a eutectic point at a eutectic temperature of about 363° C.

In an example embodiment, when the metal-semiconductor compound is formed of aluminum (Al) and silicon (Si), the metal-semiconductor compound layer has a silicon (Si) content of about 12 at % and an aluminum (Al) content of about 88 at %. The metal-semiconductor compound layer 300 may have a eutectic point at a eutectic temperature of approximately 577° C.

In an example embodiment, when the metal-semiconductor compound 300 is made of silver (Ag) and silicon (Si), the metal-semiconductor compound layer has a silicon (Si) content of about 11 at % and a silver (Ag) content of about 89 at %. The metal-semiconductor compound layer 300 may have a eutectic point at a eutectic temperature of approximately 836° C.

Thereafter, the wafer 200 may be placed in the chamber 110 (S30). For example, the processes of operations S10 and S20 may be performed in any one of the process apparatuses 11 to 14 illustrated in FIG. 12, and the wafer 200 may be transferred to another processing apparatus (e.g., the semiconductor processing apparatus 100), to perform the thin film growth process (S100).

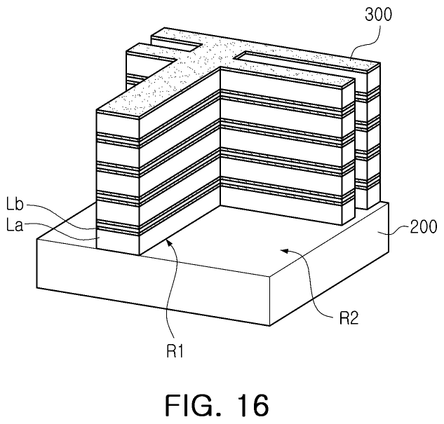

Referring to FIG. 16, a thin film growth process may be performed (S100). A first thin film La and a second thin film Lb may be grown alternately through the thin film growth process (S100) described with reference to FIGS. 4 to 9. The first thin film La may include silicon (Si), and the second thin film Lb may include silicon germanium (SiGe). The first thin film La and the second thin film Lb may be selectively formed only in the first region R1 of the wafer 200, and the first thin film La or the second thin film Lb may be not grown in second region R2. The first thin film La and the second thin film Lb may be disposed between the wafer 200 and the metal-semiconductor compound layer 300.

Thereafter, a subsequent semiconductor process may be performed on the wafer 200 (S200). The subsequent semiconductor process on the wafer 200 may include various processes. For example, the subsequent semiconductor processing on the wafer 200 may include a deposition process, an etching process, an ion process, a cleaning process, and the like. Here, the deposition process may or might not use the semiconductor processing apparatus of this embodiment. A subsequent semiconductor process may be performed on the wafer 200 to form integrated circuits and wirings required for the corresponding semiconductor device. Meanwhile, a subsequent semiconductor process on the wafer 200 may include a test process for wafer-level semiconductor device.

The wafer 200 may be individualized into each semiconductor chip, and a packaging process may be further performed to manufacture a semiconductor package including a semiconductor chip.

In an example embodiment, the semiconductor chip may be a logic chip or a memory chip. The logic chip may include a microprocessor, analog element, or digital signal processor. The memory chip may include a volatile memory chip such as Dynamic Random Access Memory (DRAM) or Static Random Access Memory (SRAM), or a non-volatile memory chip such as Phase-change Random Access Memory (PRAM), Magnetoresistive Random Access Memory (MRAM), Ferroelectric Random Access Memory (FeRAM), or Resistive Random Access Memory (RRAM).

When a thin film is formed on an entire upper surface of the wafer 200, and as the number and thickness of the deposited thin films increase, stress may occur due to a difference in a lattice constant between silicon (Si) and silicon germanium (SiGe). Accordingly, warpage may occur in the wafer 200. However, according to example embodiments of the present disclosure, a thin film may be formed only in some regions of the wafer 200 through the thin film growth process (S100). Accordingly, warpage of the wafer 200 may be prevented or reduced.

As set forth above, according to example embodiments of the technical idea of the present disclosure, a semiconductor processing apparatus uses an upper lamp, which is a flash lamp, and may heat a wafer for a short time in order of milliseconds, thereby forming a thin film more thinly from the wafer. Therefore, a semiconductor chip may be implemented with a fine pattern, and a size of the semiconductor chip may be reduced.

In addition, the thin film is not formed over an entire surface of the wafer, but is selectively formed only in some regions of the wafer, thereby preventing or reducing warpage of the wafer due to thin film deposition.

While example embodiments have been shown and described above, it will be apparent to those skilled in the art that modifications and variations could be made without departing from the scope of the present disclosure as defined by the appended claims.

What is claimed is:

1. A semiconductor processing apparatus, comprising:
a support configured to support a wafer;
a chamber comprising an upper dome that is above the support and a lower dome that is below the support;
a facility cover that at least partially surrounds the chamber;
a pre-heating unit that is below the support and is configured to heat the wafer;
an upper lamp that is on the chamber and is configured to heat the wafer;
a first process gas supply unit configured to supply a first process gas to the chamber;
a second process gas supply unit configured to supply a second process gas to the chamber;
a valve that is between the second process gas supply unit and the chamber;
a pump that is connected to the chamber and is configured to discharge gas from the chamber; and
a control unit that is configured to execute instructions stored in a non-transitory storage medium, wherein the instructions comprise controlling the pre-heating unit, the upper lamp, the first process gas supply unit, and the second process gas supply unit,
wherein the pre-heating unit comprises a first lamp that is different from the upper lamp.

2. The semiconductor processing apparatus of claim 1, wherein the instructions comprise controlling the pre-heating unit to heat the wafer before a thin film growth process is performed.

3. The semiconductor processing apparatus of claim 1, wherein:
the first process gas comprises at least one of SiH₄, Si₂H₆, SiCl₂H₂, SiCl₃H, and SiCl₄,
the second process gas comprises at least one of at least one of GeH₄, Ge₂H₆, GeH₂Cl₂, GeCl₄, and Ge₂Cl₆.

4. The semiconductor processing apparatus of claim 1, further comprising:
a first supply line that connects the second process gas supply unit and the valve;
a second supply line that connects the valve and the chamber; and
an exhaust line that connects the valve and the pump.

5. The semiconductor processing apparatus of claim 4, wherein the instructions further comprise controlling the valve so that the first supply line is connected to the second supply line or the exhaust line.

6. The semiconductor processing apparatus of claim 1, wherein the instructions further comprise controlling the valve such that the first process gas is supplied to the chamber during a first time period and such that the first process gas and the second process gas are supplied to the chamber during a second time period that is subsequent to the first time period.

7. The semiconductor processing apparatus of claim 6, wherein the instructions further comprise controlling the valve such that during the first time period, the second process gas is not supplied to the chamber.

8. The semiconductor processing apparatus of claim 1, wherein the instructions further comprise controlling the pre-heating unit to heat the wafer from a first temperature to a second temperature and to heat the wafer until a first time point, and wherein the instructions further comprise controlling the upper lamp to heat the wafer to a third temperature that is greater than the second temperature and to heat the wafer until a second time point after the first time point.

9. The semiconductor processing apparatus of claim 8, wherein an operating time of the upper lamp in which the upper lamp heats the wafer to the third temperature is in a range of about 0.1 ms to about 5 ms.

10. The semiconductor processing apparatus of claim 8, wherein the instructions further comprise controlling the pre-heating unit to maintain the third temperature of the wafer after the upper lamp heats the wafer to the third temperature.

11. The semiconductor processing apparatus of claim 8, wherein the first process gas supply unit is configured to supply the first process gas to the chamber at a constant flow rate.

12. The semiconductor processing apparatus of claim 8, wherein the upper lamp is a xenon arc lamp.

13. The semiconductor processing apparatus of claim 1, wherein the pre-heating unit is below the chamber.

14. The semiconductor processing apparatus of claim 1, wherein the instructions further comprise controlling the pre-heating unit and the upper lamp to operate alternately and repeatedly.

15. The semiconductor processing apparatus of claim 1, further comprising a reflector that is on the chamber and the upper lamp and that is configured to reflect light emitted from the upper lamp.

16. A semiconductor processing apparatus, comprising:
a chamber that comprises a support that is configured to support a wafer;
a pre-heating unit that is below the support;
an upper lamp that is above the support; and
a control unit that is configured to execute instructions stored in a non-transitory storage medium to control the semiconductor processing apparatus to perform operations comprising:
depositing metal on the wafer;
heating the metal to form a metal-semiconductor compound layer on the wafer; and
growing a thin film between the wafer and the metal-semiconductor compound layer,
wherein growing the thin film comprises forming a first thin film and forming a second thin film on the first thin film,
wherein forming the first thin film comprises:
supplying a first process gas to the chamber;
heating the wafer using the pre-heating unit below the wafer; and
heating the wafer using the upper lamp to grow the first thin film.

17. The semiconductor processing apparatus of claim 16, wherein the first thin film comprises silicon (Si), and wherein the second thin film comprises germanium (SiGe).

18. The semiconductor processing apparatus of claim 16, wherein forming the second thin film comprises:
supplying the first process gas and a second process gas to the chamber; and
heating the wafer using the upper lamp to grow the second thin film.

19. The semiconductor processing apparatus of claim 16, wherein:
the wafer comprises a first region and a second region,
the metal-semiconductor compound layer is on the first region and is not on the second region, and
the first thin film and the second thin film are on the first region.

20. A semiconductor processing apparatus, comprising:
a support configured to support a wafer;
a chamber comprising an upper dome that is above the support and a lower dome that is below the support;
a facility cover that at least partially surrounds the chamber;
a pre-heating unit that is below the support and is configured to heat the wafer;
an upper lamp that is on the chamber and is configured to heat the wafer;
a gas inlet on a first side of the chamber;
a gas outlet on a second side of the chamber;
a first process gas supply unit that is connected to the gas inlet and is configured to supply a first process gas to the chamber;
a second process gas supply unit that is connected to the gas inlet and is configured to supply a second process gas to the chamber;
a valve that is between the second process gas supply unit and the chamber;
a pump that is connected to the gas outlet and is configured to discharge gas from the chamber; and
a control unit that is configured to execute instructions stored in a non-transitory storage medium, wherein the instructions comprise controlling the pre-heating unit, the upper lamp, the first process gas supply unit, and the second process gas supply unit,
wherein the pre-heating unit comprises a first lamp that is different from the upper lamp,
wherein the instructions comprise controlling the pre-heating unit to heat the wafer before a thin film growth process is performed, and
wherein the instructions comprise controlling the upper lamp to heat the wafer when the thin film growth process is performed.
